(19) United States
(12) Patent Application Publication
(10) Pub. No.: US 2025/0226810 A1
(43) Pub. Date: Jul. 10, 2025

(54) RESONATOR INCLUDING AN OFFSET PERIPHERAL LIGHT GUIDE

(71) Applicant: COMMISSARIAT A L’ÉNERGIE ATOMIQUE ET AUX ENERGIES ALTERNATIVES, Paris (FR)

(72) Inventors: Thomas FURCATTE, Grenoble Cedex 09 (FR); Marc SANSA PERNA, Grenoble Cedex 09 (FR); Sébastien HENTZ, Grenoble Cedex 09 (FR)

(73) Assignee: COMMISSARIAT A L’ÉNERGIE ATOMIQUE ET AUX ENERGIES ALTERNATIVES, Paris (FR)

(21) Appl. No.: 19/016,646

(22) Filed: Jan. 10, 2025

(30) Foreign Application Priority Data
Jan. 10, 2024 (FR) FR2400228

(51) Int. Cl. H03H 9/17; G02F 1/01

(52) U.S. Cl. CPC H03H 9/17; G02F 1/011; G02F 2203/15

(57) ABSTRACT

Resonator (30) including:
an actuator (38),
a resonant structure (31) configured to oscillate by being periodically deformed at a resonant frequency (fᵣ), because of the effect of the actuator,
a peripheral light guide (32) extending around the resonant structure and configured to oscillate, by deforming periodically, being driven by the resonant structure,
   the resonator being characterised in that:
the resonant structure (31) is thicker than the peripheral light guide,
the peripheral light guide is held at a distance from the resonant structure by at least one ancho.

### TECHNICAL FIELD

The technical field of the invention concerns mechanical resonators notably usable to form an optomechanical oscillator.

### PRIOR ART

Use of an optomechanical oscillator enables the formation of a periodic electronic signal the amplitude and the period of which are controlled. One possible application is the formation of a clock signal.

In prior art devices, the optomechanical oscillators include a source of light and a resonator. Because of the effect of optical coupling, some of the light emitted by the light source is extracted and propagated in the resonator. When the resonant structure oscillates, at a resonant frequency, the efficacy of the optical coupling at a given wavelength varies at the resonant frequency. This results in a periodic variation of the quantity of light extracted in the resonator.

As a general rule, in optomechanical devices the thickness of the structures is limited to a few hundred nanometres in such a manner as to maintain a single optical propagation mode. For simplicity, the resonator is usually extracted from a single layer of fixed thickness. The reason is to limit the risks of intermodal coupling, which destroys practical use.

When these resonators are inserted in oscillators, these thickness restrictions prevent the oscillator from performing well. Performance is quantified by a figure of merit, termed the phase noise of the oscillator, that has to be minimised. The phase noise depends in particular on the “filtering power” of the resonator, that is to say its mechanical quality factor (to be maximised), which can be increased by thickening the resonator.

The publication by Beyazoglu et al. “A multimaterial Q-boosted low phase noise optomechanical oscillator”, describes an optomechanical oscillator offering a low noise level. The oscillator includes a polycrystalline silicon ring surrounded by a silicon nitride ring, forming a peripheral light guide. The two rings are concentric. The polycrystalline silicon ring forms a resonant structure, caused to vibrate by electrodes, by a capacitive effect. The vibration of the resonant structure drives movement of the peripheral light guide. The ring forming the light guide is thinner than the ring forming the resonant structure. Two different materials are used to form the resonant structure, caused to vibrate by electrodes, and the peripheral light guide, respectively. The peripheral light guide extends in contact with the resonant structure, all around the latter. In order to enable confinement of light, the light guide must have a certain width.

The inventors propose an optomechanical resonator offering a high mechanical quality factor while limiting the number of optical modes. It also has reduced sensitivity to temperature fluctuations, making it an ideal candidate for use in oscillators. The objective may be to generate an amplitude-modulated signal the power and the period of which are stable.

### STATEMENT OF INVENTION

A first object of the invention is a resonator including:
an actuator,
a resonant structure configured to oscillate by being periodically deformed at a resonant frequency, because of the effect of the actuator,
a peripheral light guide extending around the resonant structure and configured to oscillate, by deforming periodically, being driven by the resonant structure,
   wherein:
the resonant structure is thicker than the peripheral light guide,
the peripheral light guide is held at a distance from the resonant structure by at least one anchor.

An intermediate space may notably extend between the peripheral light guide and the resonant structure, the intermediate space being filled by a gas or a liquid or a vacuum.

According to one possibility:
the thickness of the peripheral light guide is between 100 nm and 600 nm;
the thickness of the resonant structure is at least twice or at least three times greater than the thickness of the peripheral light guide.

The thickness of the resonant structure may be between 600 nm and 1 mm, and preferably between 1 μm and 50 μm.

The resonant structure may be disposed facing at least one actuator electrode, the actuator electrode being spaced from the resonant structure by an airgap, the actuator electrode forming the actuator, being configured to generate oscillation of the resonant structure by a capacitive effect, for example.

The actuating electrode may extend in the intermediate space.

According to one possibility:
the resonant structure includes a piezoelectric material,
the resonator includes two actuator electrodes, on respective opposite sides of the resonant structure, the actuator electrodes forming the actuator.

The resonant structure and the peripheral waveguide may be formed of the same material.

The resonant structure may have a cylindrical shape, with a circular or polygonal base, or an annular shape.

The resonant frequency may be above 1 MHz.

A second object of the invention is an optomechanical oscillator including:
a light source configured to emit a light beam and to propagate the latter along a resonator,
the resonator being configured so that the periodic oscillation of the resonator drives periodic modulation of a light power of the light beam,
wherein the resonator is a resonator according to the first object of the invention.

The oscillator may include a photodetector configured to detect the light beam that has propagated along the resonator. The photodetector may be configured to feed a feedback signal to the resonator.

The invention will be better understood after reading the description of embodiments given in the remainder of the description with reference to the figures listed below.

### FIGURES

FIG. 1A and FIG. 1B show the main components of an optomechanical oscillator.

FIG. 2 shows an oscillation of the optical power delivered by an optomechanical oscillator as described with reference to FIGS. 1A and 1B.

FIG. 3A is a three-dimensional view showing a resonant structure driving a peripheral light guide with an oscillation movement.

FIG. 3B shows a view in section of the resonant structure and the peripheral light guide described with reference to FIG. 3A. The section plane corresponds to a median plane of the peripheral light guide.

FIG. 3C is a view in section of the resonant structure described with reference to FIG. 3B, in a transverse section plane perpendicular to the median plane of the peripheral light guide.

FIG. 3D shows the configuration described with reference to FIGS. 3A to 3C with a capacitive-effect actuator.

FIG. 4 shows the distribution of the electromagnetic field in a cylindrical multimode light guide 1 μm thick, along the vertical axis, and with cylindrical symmetry.

FIG. 5A shows a second embodiment of the invention in a transverse section plane as defined above.

FIG. 5B shows the second embodiment of the invention in a section plane corresponding to the median plane of the peripheral light guide.

FIGS. 6A to 6I show a method of producing the resonator as described with reference to FIG. 3D.

FIG. 7 shows a third embodiment in which the resonant structure is actuated by a piezoelectric effect.

### DESCRIPTION OF PARTICULAR EMBODIMENTS

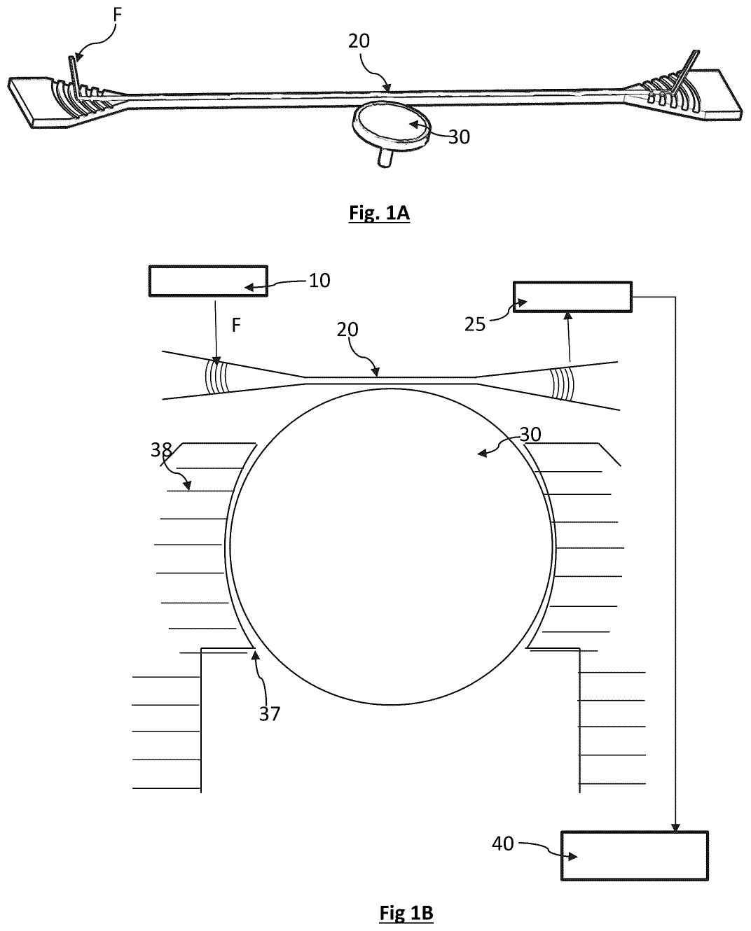

FIGS. 1A and 1B show components of an optomechanical oscillator. The oscillator includes a light source 10 emitting a light beam F. In this example the light beam is transported by a light guide 20 to a photodetector 25.

The oscillator includes a resonator 30 extending along the light guide 20. The resonator 30 is configured to oscillate, by being deformed, at a resonant frequency fᵣ. The resonant frequency is preferably above 1 MHz and is preferably in the range 1 MHz-100 GHz. In this example the resonator is configured to be driven with an in-plane vibration movement, depending on the resonant frequency, under the effect of capacitive actuation exerted by an actuator 38. The actuator 38, shown in FIG. 1B, is fixed relative to the resonator 30. The actuator 38 is situated on either side of the resonator 30. The electrostatic actuation is effected by means of an airgap 37, extending between the fixed actuator 38 and the resonator 30. The capacitive actuation is controlled by a control unit 40.

The photodetector is configured to form an electrical signal modulated at a modulation frequency, at the resonant frequency of the resonator. The frequency-modulated signal may be used to form a clock signal. The control unit 40 is fed via a resulting feedback loop of the photodetector 25.

In this example the resonator 30 is a cylinder with a circular base. The resonator may extend with a different geometry, for example a cylinder with a polygonal base or a ring.

The light guide 20 may be produced on the surface layer of Si of a silicon on insulator (SOI) type substrate. The cross section may for example be a few hundred 15 nm by a few hundred nm, for example of the order of 600 nm×200 nm. By cross section is meant a section in a plane perpendicular to the light propagation axis. The light guide 20 is preferably configured for propagation in a single mode, at a wavelength that can be 1550 nm, the usual wavelength in the field of telecommunications.

The resonator 30 is optically coupled to the light guide 20, for example by 20 evanescent coupling. The distance between the resonator and the light guide 20 is for example 100 nm. Thus when a light beam propagates along the light guide 20 part of the light beam is extracted and propagates in the resonator 30.

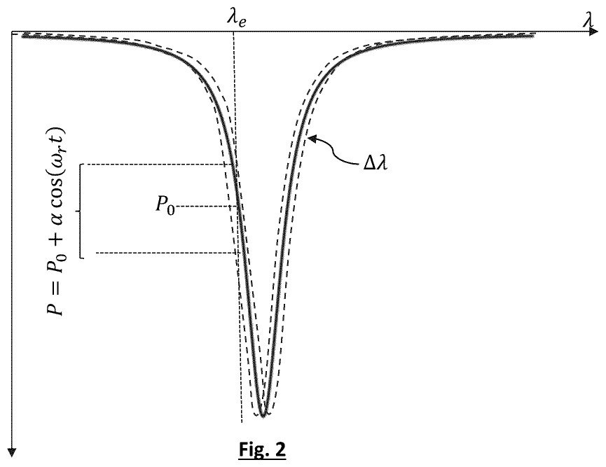

FIG. 2 depicts an optical coupling pass band between the light guide 20 and the resonator 30. The abscissa axis corresponds to the optical wavelength. The 25 ordinate axis corresponds to the light power extracted from the optical light guide 20 by the resonator 30. The curve in solid line represents the fixed configuration, in which the resonator is fixed. Because of the effect of oscillation of the resonator, the optical coupling between the waveguide and the resonator varies. In FIG. 2 this is reflected in a periodic variation of the coupling pass band between the two dashed line curves, 30 reflecting a spectral offset of the light guide 20/resonator 30 coupling.

In FIG. 2 the vertical dashed line corresponds to the emission wavelength λₑ of the beam F propagating in the light guide 20. Due to the periodic variation of the coupling pass band the power of the optical beam F propagating in the light guide 20 is modulated at an angular frequency ωᵣ, in accordance with the expression:

P=P₀+α cos (ωᵣt) (1)

where:
P₀ is the power propagating in the light guide “at equilibrium”, that is to say with no oscillation of the peripheral light guide 32;
a is the amplitude of modulation, that is to say the variation of power extracted in the peripheral light guide 32 because of the effect of the oscillation of the resonant structure 31;

ωᵣ=2πfᵣ (2)

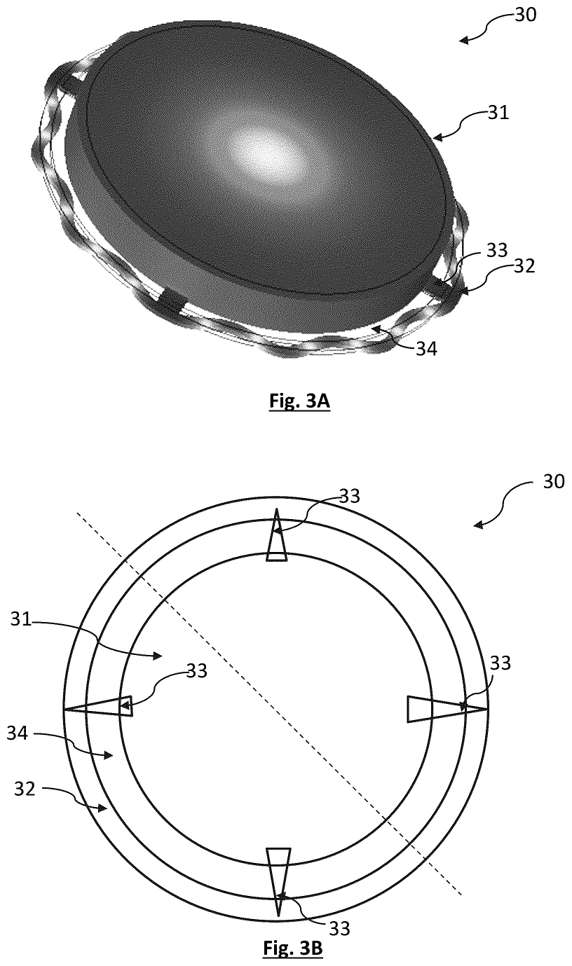

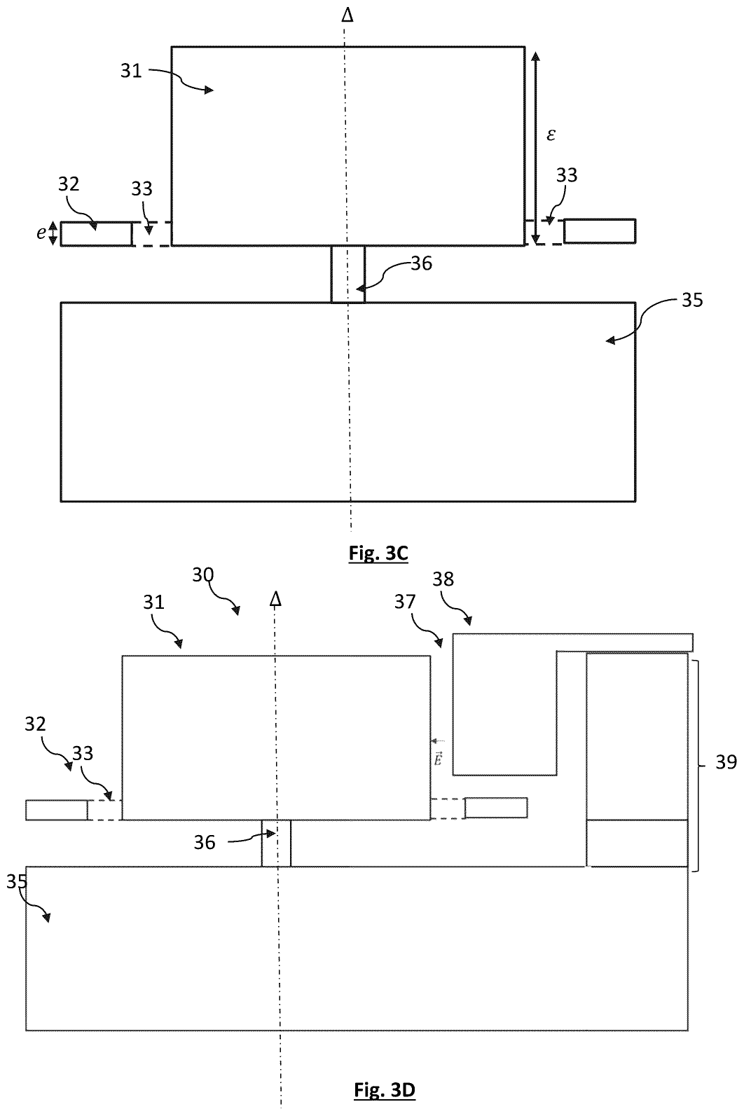

FIGS. 3A to 3D show an example of a resonator 30 according to the invention, which can be integrated into an oscillator as described with reference to FIGS. 1A and 1B. FIG. 3A is a perspective view. FIGS. 3B and 3D are sectional views.

One particular feature of the resonator is that the mechanical quality factor is high, while the sensitivity to temperature fluctuations is low.

As part of an oscillator, resonator 30 acts as band-pass filter, attenuating the noise sources with frequency components lying outside of the resonator's pass band. The width of this pass band is inversely proportional to the mechanical quality factor, and therefore the oscillation movement of the resonator will have greater spectral purity if benefits from high quality factors. The modulation of the optical beam by the optomechanical transducer system also benefits to this improved spectral purity. It is therefore important to have a high mechanical quality factor Q. The greater the thickness of a mechanical resonator, the higher the quality factor.

The mechanical quality factor of the resonator corresponds to the width of the resonance peak of the oscillation resonator. When the resonator is inserted in an oscillator, the figure of merit of the latter, also known as phase noise, must be minimised. It can be shown that the phase noise depends on the ratio 1/Q², Q being the mechanical quality factor. The point here is to work with the highest possible mechanical quality factors.

The noise spectral density is also considered to include a thermal component that can be considered as inversely proportional to the mass of the resonator, therefore to its thickness.

Accordingly, in order to increase the mechanical quality factor and reduce the sensitivity to noise it is preferable to increase the thickness of the resonator 30. Nevertheless, it is preferable for the light to propagate through a structure the thickness of which is sufficiently small to allow propagation of only monomode light in the cross section of the guide.

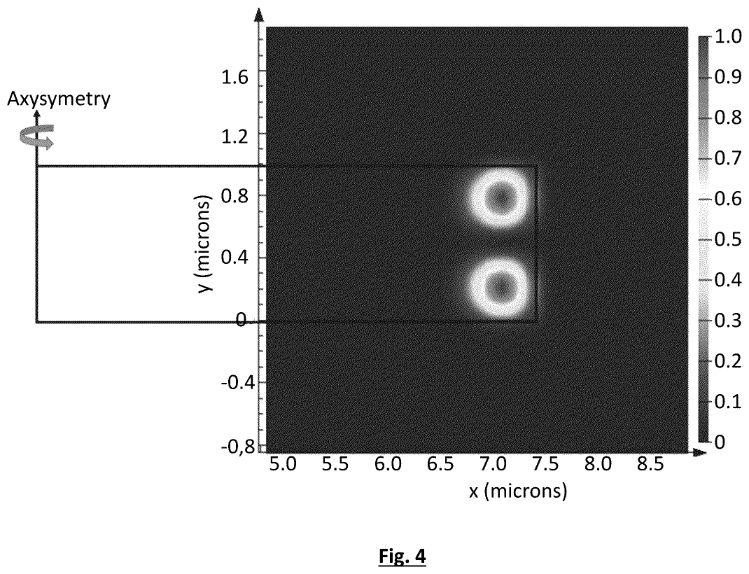

FIG. 4 shows a cross section of a light guide having a thickness of 1 μm. It shows a spatial distribution of the intensity of an electric field in the cross section of the light guide. The grey levels represent the electric field intensity. Two maxima are observed in each cross section: this indicates that the light propagates in more than one mode, which is undesirable, because of the risk of intermodal coupling.

The resonator 30, shown in FIGS. 3A to 3D includes a resonant structure 31 configured to be set in vibration by an actuator. The resonator also features a peripheral light guide 32 extending around the resonant structure at a non-zero distance from the latter. Anchors 33 connect the peripheral light guide 32 to the resonant structure 31. As represented in FIG. 3B, the anchors are arranged to transmit the oscillations of the resonant structure 31 to the peripheral light guide 32, while keeping the peripheral light guide 32 away from the resonant structure 31.

In FIG. 3A the peripheral light guide is shown:
shaded, when it is driven with an oscillation movement transmitted by the anchors 33;
by a line, when stationary: it then describes a ring around the resonant structure 32.

An intermediate space 34, or interspace, extends between the peripheral light guide 32 and the resonant structure 31. The intermediate space 34 extends around the resonant structure 31, between each anchor 33. Accordingly, along at least 80%, even 90% of the contour of the peripheral light guide 32, the latter is separated from the resonant structure 31 by the intermediate space 34. The intermediate 34 is filled by the ambient medium: this may be a gas, such as air, or a vacuum, or a liquid the refractive index of which is lower than that of the material forming the peripheral waveguide.

FIG. 3B shows cross-sectional view of the elements shown in FIG. 3A in a section plane corresponding to a mid-plane of the peripheral light guide 32.

The spacing of the peripheral light guide 32 relative to the resonant structure 31 enables to confine the light propagating in the peripheral light guide. The resonant structure 31 and the peripheral light guide 32 can therefore be formed of the same material, for example Si. The anchors 33 can be formed of the same material, the effect of the anchors on the confinement of the light being negligible due to the limited contact area with the contour of the peripheral light guide: typically less than 20%, even less than 10%, even less than 5% of the contour of the peripheral light guide facing the resonant structure 31 is occupied by an anchor.

FIG. 3C shows a section through the thickness of part of the resonator, along a dashed line shown in FIG. 3B. The resonant structure 31, set in motion by an actuator, extends to a thickness & preferably between 600 nm and 1 mm, and more preferably between 1 μm and 50 μm. The thickness e of the peripheral light guide 32 is preferably between 50 nm and 600 nm, or between 100 nm and 600 nm, for example 200 nm. The thickness of the resonant structure 31 is generally at least twice or at least three times greater than the thickness of the peripheral light guide 32.

The resonant structure 31 is connected to a base 35 by a pillar 36. Both the resonant structure 31 and the peripheral light guide 32 extend around a central axis A. During oscillations of the resonant structure 31, the central axis A remains fixed. The central axis A preferably forms an axis of symmetry of the assembly formed by the resonant structure 31 and the peripheral light guide 32. In FIG. 3C the anchors 33 are shown in dashed line.

FIG. 3D shows an actuating electrode 38, enabling actuation of the resonant structure by capacitive effect. The actuating electrode serves as the actuator. An insulating airgap 37 extends between the actuating electrode 38 and the resonant structure 31. The actuator is formed by an electrode polarised by an alternating current generating an electric field E in the airgap. The thickness of the airgap is of the order of around one hundred nm. The airgap 37 is preferably filled by the ambient medium: gas, vacuum or liquid. The actuator electrode is held by a support 39 connected to the base 35. In FIG. 3D there have been represented in dashed line the anchors 33 distributed, preferably symmetrically with respect to the axis A, between the peripheral light guide 32 and the resonant structure 31.

FIGS. 5A and 5B show an embodiment in which the actuating electrode 38 extends between the resonant structure 31 and the peripheral light guide 32. FIGS. 5A and 5B are cross-sections on the transverse plane and on the median plane respectively, as defined above. Such an embodiment increases the area of the capacitive coupling between the actuating electrode 38 and the resonant structure 31. This results in improved coupling between the actuating electrode 38 and the resonant structure 31. The airgap 37 then corresponds to a part of the intermediate space 34 extending between the resonant structure 31 and the peripheral light guide 32.

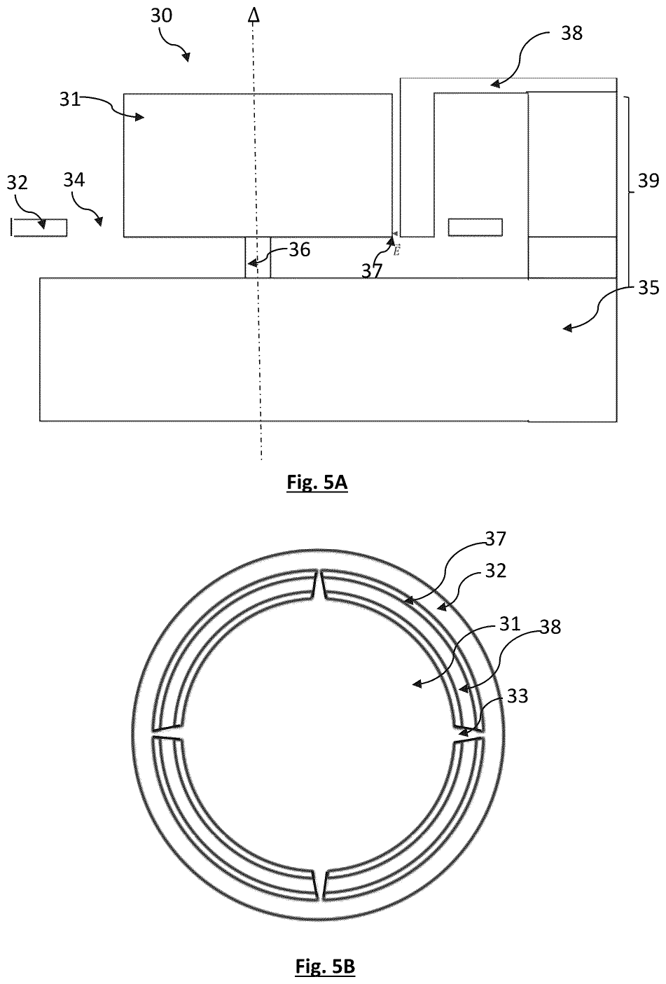

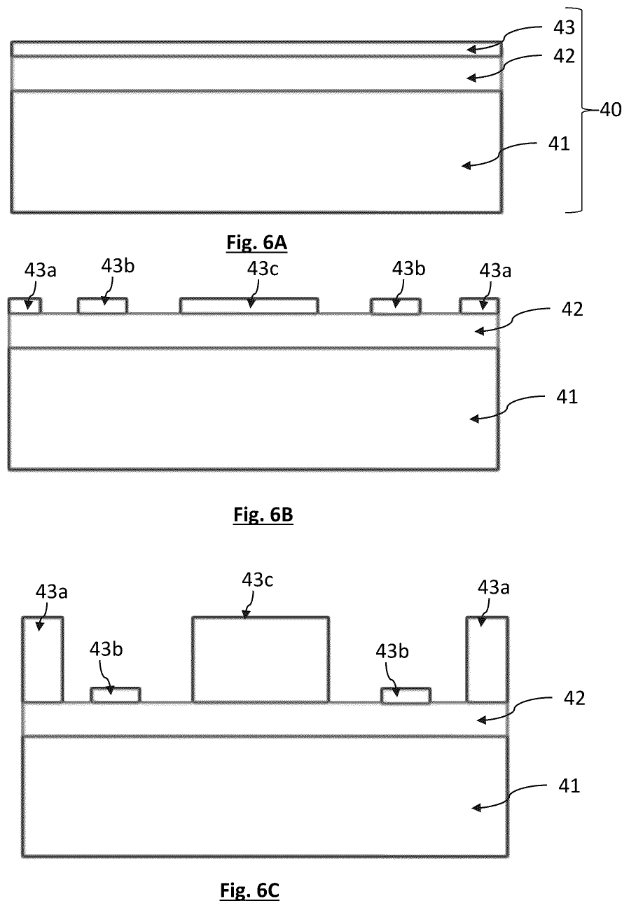

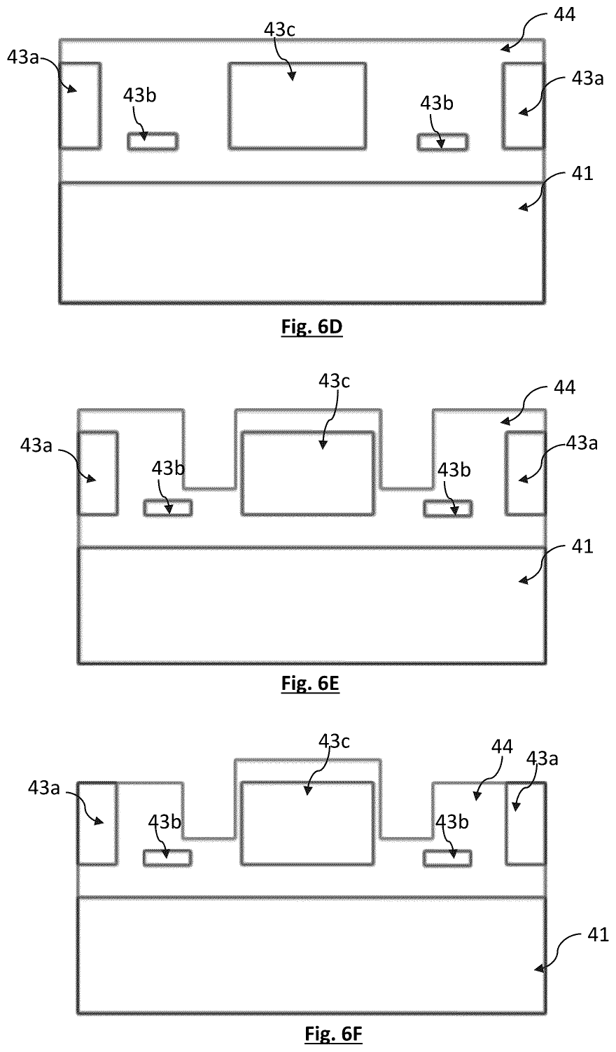

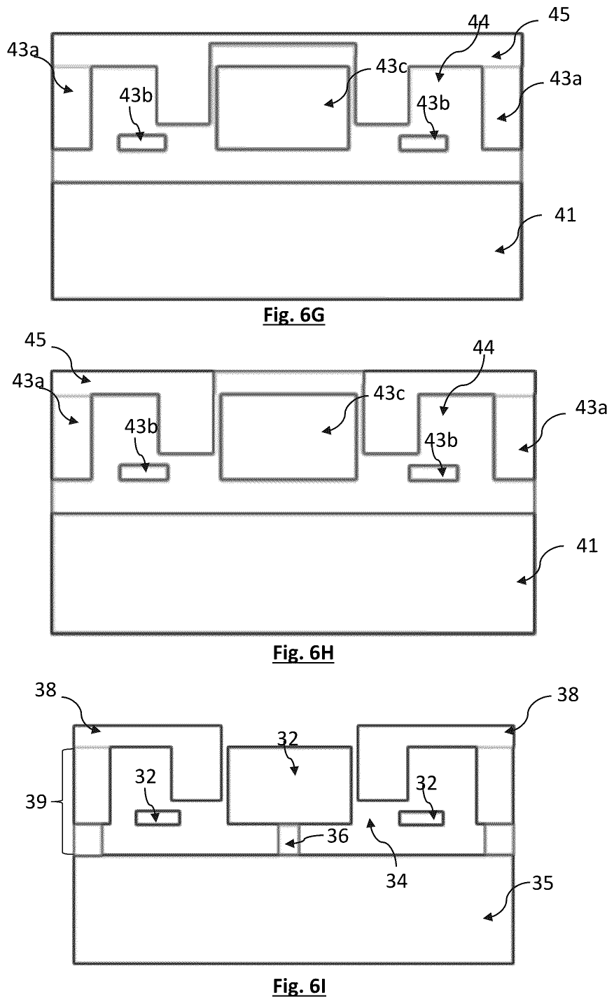

FIGS. 6A to 6I show the main steps of a method of manufacturing a resonator 30 as described with reference to FIG. 3D. An SOI type substrate 40 is provided, including a stack comprising a bulk layer 41, an intermediate layer 42 of SiO₂ and a thinned upper layer 43 of Si, the thickness of the latter being for example 220 nm (see FIG. 6A).

The upper layer 43 is etched to define a plurality of elements (see FIG. 6B). An annular peripheral element 43a forms a base of an actuator electrode support. A cylindrical central element 43c corresponds to a base of the resonant structure. An annular element 43b forms the peripheral light guide and, locally, the anchors, the latter extending between the central element 43c and the annular peripheral element 43a. The central element 43c and the element 43a are grown epitaxially (see FIG. 6C).

A layer 44 of SiO₂ is deposited (see FIG. 6D), and is then deep etched, to define the central element 43c (see FIG. 6E). Surface etching is applied so as to free the upper surface of the stack around the central element (see FIG. 6F).

A conductive, for example metal, layer 45 is applied at the level of the upper surface of the stack (see FIG. 6G). The conductive layer 45 is then thinned (see FIG. 6H). The SiO₂ layer 44 is then removed by wet etching, allowing residues to remain intended to form a pillar 36 and a part of the support 39 (see FIG. 6I). In FIG. 6I there are seen the main elements forming the resonator 30 as described with reference to FIG. 3D.

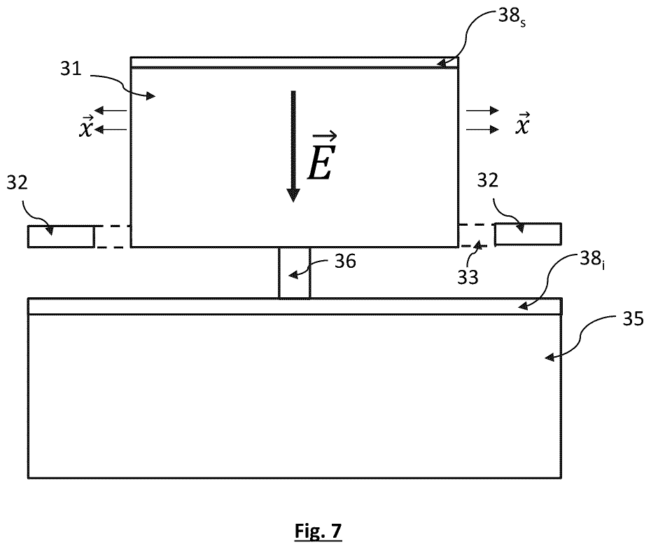

FIG. 7 shows a third embodiment in which the resonant structure 31 is actuated piezoelectrically. Elements 32, 35 and 36 are as described with reference to FIG. 4D or 5A. The resonant structure is formed of a piezoelectric material, for example aluminium nitride (AlN), lithium niobate (LNO). The base 35 includes a lower electrode 38ᵢ. The resonant structure includes an upper electrode 38ₛ. Under the effect of an amplitude-modulated electric field E between the upper electrode 38ₛ and the lower electrode 38ᵢ, the resonant structure deforms, along a vector \vec{x} as represented in FIG. 7. The electrodes may be made of metal, metal alloy or doped semiconductor.

The invention enables a resonator to be formed that is configured to amplitude-modulate a light beam in a stable manner and at a stabilised frequency. When such a resonator is integrated into an oscillator, that enables a clock signal to be formed the amplitude and the frequency of which are controlled.

1. A Resonator, comprising:
an actuator,
a resonant structure configured to oscillate, deforming periodically at a resonant frequency, by the actuator,
a peripheral light guide extending around the resonant structure and configured to oscillate, deforming periodically, by being driven by the resonant structure,
wherein:
the resonant structure is thicker than the peripheral light guide,
the peripheral light guide is held at a distance from the resonant structure by at least one anchor,
an intermediate space extends between the peripheral light guide and the resonant structure, the intermediate space being filled by a gas or a liquid or a vacuum.

2. The resonator according to claim 1, wherein:
the thickness of the peripheral light guide is between 100 nm and 600 nm;
the thickness of the resonant structure is at least twice or at least three times greater than the thickness of the peripheral light guide.

3. The resonator according to claim 2, wherein the thickness of the resonant structure is between 600 nm and 1 mm.

4. The resonator according to claim 1, wherein the thickness of the resonant structure is between 1 μm and 50 μm.

5. The resonator according to claim 1, wherein the resonant structure is arranged opposite at least one actuating electrode, the actuating electrode being spaced from the resonant structure by an airgap, the actuating electrode, forming the actuator, being configured to generate oscillation of the resonant structure by capacitive effect.

6. The resonator according to claim 1, wherein the actuating electrode extends in the intermediate space.

7. The resonator according to claim 1, wherein:
the resonant structure includes a piezoelectric material,
the resonator comprises two actuating electrodes, on respective opposite sides of the resonant structure, the actuating electrodes forming the actuator.

8. The resonator according to claim 1, wherein the resonant structure and the peripheral waveguide are formed of the same material.

9. The resonator according to claim 1, wherein the resonant structure has a cylindrical shape, with a circular or polygonal base, or an annular shape.

10. The resonator according to claim 1, in wherein the resonant frequency is above 1 MHz.

11. An optomechanical oscillator including:
a light source configured to emit a light beam and to propagate the light beam along a resonator,
the resonator being configured so that the periodic oscillation of the resonator result in periodic modulation of a light power of the light beam,
wherein the resonator is the resonator according to claim 1.
